(19) United States
(12) Patent Application Publication
(10) Pub. No.: US 2007/0284338 A1
(43) Pub. Date: Dec. 13, 2007

(54) Chemical mechanical polishing method

(76) Inventors: Yukiteru Matsui, Yokohama-shi (JP); Takatoshi Ono, Odawara-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/808,148

(22) Filed: Jun. 7, 2007

(30) Foreign Application Priority Data
Jun. 8, 2006 (JP) 2006-160083

(51) Int. Cl. H01L 21/461; C03C 15/00; H01L 21/302

(52) U.S. Cl. 216/89; 438/692; 438/693

(57) ABSTRACT

A chemical mechanical polishing method includes bringing a body to be polished into contact with a polishing pad mounted on a rotating polishing table while feeding a polishing slurry to the polishing pad. The polishing pad is formed of a laminate comprising a first pad layer in contact with the body, and a second pad layer positioned on a side of the polishing table with a water-proof film being interposed therebetween wherein the first pad layer is provided with a pad-cooling hole reaching the second pad layer and the second pad layer is provided with a cooling trench radially disposed to interconnect with the pad-cooling hole. The polishing slurry is fed to a surface of the first pad layer to polish the body, while permitting part of the polishing slurry to pass through the pad-cooling hole to the cooling trench.

### CROSS-REFERENCE TO RELATED APPLICATIONS

This application is based upon and claims the benefit of priority from prior Japanese Patent Application No. 2006-160083, filed Jun. 8, 2006, the entire contents of which are incorporated herein by reference.

### BACKGROUND OF THE INVENTION

1. Field of the Invention

This invention relates to a chemical mechanical polishing method and to a method for manufacturing a semiconductor device. In particular, this invention relates to a chemical mechanical polishing method which is suitable for use in the manufacture of a high-speed device such as a high-speed logic LSI, a system LSI, a memory logic hybrid LSI, etc.

2. Description of the Related Art

In recent years, a chemical mechanical polishing method (CMP) has been mainly employed as a planarization method to be used in the manufacturing process of a semiconductor device. In this CMP, the planarization performance thereof is influenced by the load dependency of polishing rate. Namely, as the load dependency of polishing rate is increased, the polishing rate of projected portion to which a higher load is applied would become higher and the polishing rate of recessed portion to which a lower load is applied would become lower. As a result, the ratio in polishing rate between the recessed portion and the projected portion is increased and hence the planarization performance of CMP tends to be enhanced.

However, when a high load is applied to a projected portion, the friction between a polishing head and a polishing pad is caused to increase, thus raising the surface temperature of polishing pad. When the surface temperature of polishing pad exceeds over 60° C., it is no longer possible to raise the polishing rate even if the load is increased, thus prolonging the polishing time and also deteriorating the planarization performance. The reason for this may be assumably attributed to the fact that since the glass transition temperature of polyurethane employed as a structural material for the polishing pad is 60-70° C., the surface layer of the polishing pad is caused to soften due to the rise in temperature, thus deteriorating the sustaining state of abrasive grains.

Although there has been proposed to provide a cooling mechanism for passing cooling water to the polishing table in order to lower the surface temperature of polishing pad (see for example, JP-A 8-216023), it is difficult to exert the cooling effect thereof on a wafer due to low thermal conductivity of the polishing pad, thus making it difficult to suppress the rise in temperature of the surface of polishing pad ultimately.

The problem of the deterioration of polishing rate due to the rise in temperature of the surface of polishing pad as described above tends to become more prominent as the diameter of wafer increases from 200 mm to 300 mm.

Incidentally, although there has been proposed to provide a large number of cooling holes and a trench connecting these cooling holes with each other on the surface of polishing pad (see for example, JP Patent No. 3042593 and JP-A 2001-150333), this proposal is accompanied with the problem that the water infiltrated from a peripheral portion of polishing pad is permitted to ooze out of the cooling holes to the surface of polishing pad due to the application of load by the polishing head, thus diluting the polishing slurry and hence lowing the polishing rate.

### BRIEF SUMMARY OF THE INVENTION

According to one aspect of the present invention, there is provided a chemical mechanical polishing method, which comprises bringing a body to be polished into contact with a polishing pad mounted on a rotating polishing table while feeding a polishing slurry to the polishing pad, to chemically and mechanically polish the body; wherein the polishing pad is formed of a laminate comprising a first pad layer in contact with the body, and a second pad layer positioned on a side of the polishing table with a water-proof film being interposed therebetween, the first pad layer has a pad-cooling hole reaching the second pad layer, the second pad layer has a cooling trench radially disposed to interconnect with the pad-cooling hole, and the polishing slurry is fed to a surface of the first pad layer to polish the body, while permitting part of the polishing slurry to pass through the pad-cooling hole to the cooling trench.

### BRIEF DESCRIPTION OF THE SEVERAL VIEWS OF THE DRAWING

FIG. 1 is a cross-sectional view showing the polishing table and polishing pad of polishing apparatus to be employed in the chemical mechanical polishing method according to one embodiment of the present invention;

FIG. 2A is a plan view showing a top surface of the first pad layer shown in FIG. 1;

FIG. 2B is a plan view showing an underside surface of the second pad layer shown in FIG. 1;

FIG. 3 is a cross-sectional view showing the polishing table and polishing pad of polishing apparatus to be employed in the chemical mechanical polishing method according to another embodiment of the present invention;

FIG. 4 is a cross-sectional view showing the polishing table and polishing pad of polishing apparatus to be employed in the chemical mechanical polishing method according to a further embodiment of the present invention;

FIG. 5A is a plan view showing a top surface of the first pad layer shown in FIG. 4;

FIG. 5B is a plan view showing an underside surface of the second pad layer shown in FIG. 4;

FIG. 6 is a cross-sectional view showing the polishing table and polishing pad of polishing apparatus to be employed in the chemical mechanical polishing method according to a further embodiment of the present invention;

FIGS. 7A and 7B respectively shows a cross-sectional view illustrating a process for forming an element isolation structure by means of CMP of an oxide film;

FIG. 8 is a cross-sectional view showing the polishing table and polishing pad of polishing apparatus according to Comparative Example 1;

FIG. 9A is a plan view showing a top surface of the first pad layer shown in FIG. 8;

FIG. 9B is a plan view showing an underside surface of the second pad layer shown in FIG. 8;

FIG. 10 is a cross-sectional view showing the polishing table and polishing pad of polishing apparatus according to Comparative Example 2;

FIG. 11A is a plan view showing a top surface of the first pad layer shown in FIG. 10;

FIG. 11B is a plan view showing an underside surface of the second pad layer shown in FIG. 10;

FIG. 12 is a graph illustrating the relationships between the polishing pressure and the surface temperature of the first pad layer and polishing rate in Example 3; and

FIG. 13 is a graph illustrating the relationships between the polishing pressure and the surface temperature of the first pad layer and polishing rate in Comparative Example 2.

### DETAILED DESCRIPTION OF THE INVENTION

Next, various embodiments of the present invention will be explained with reference to drawings.

Incidentally, the present invention should not be construed as being limited to the following embodiments but should be understood as including various modifications that can be carried out without departing the gist of the present invention.

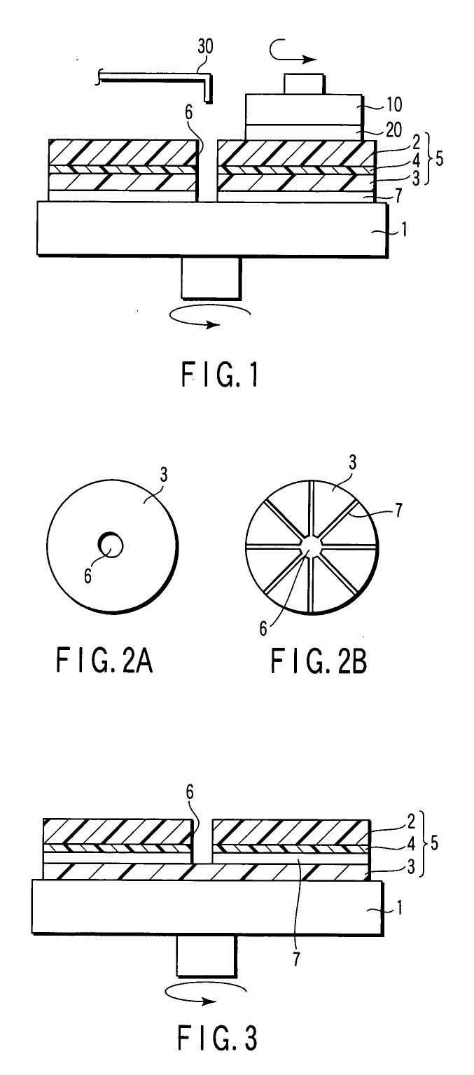

FIG. 1 is a cross-sectional view showing the polishing table and polishing pad of a polishing apparatus to be employed in the chemical mechanical polishing method according to one embodiment of the present invention. Referring to FIG. 1, a polishing pad 5 is attached to the surface of a polishing table 1. The polishing pad 5 is formed of a laminate of a rigid first pad layer 2 and a soft second pad layer 3 with a water-proof film 4 being interposed therebetween. FIG. 2A is a top plan view of the first pad layer 2 and FIG. 2B is a bottom plan view of the second pad layer 3.

As for the material for the first pad layer 2, it is possible to employ a rigid polyurethane, etc. in order to secure a local flatness. As for the material for the second pad layer 3, it is possible to employ unwoven cloth formed of soft foamed polyurethane in order to secure global flatness. As for the water-proof film 4, it is possible to employ an adhesive such as an acrylic adhesive or a rubber adhesive.

The polishing pad 5 formed of the first pad layer 2, the water-proof film 4 and the second pad layer 3 is provided with a pad-cooling hole 6 which is located in the vicinity of the center of the polishing pad to which the slurry is designed to be dropped. Although there is not any particular limitation with respect to the diameter of the pad-cooling hole 6, it may be in the range of 1 mm to 20 mm or so in general. Namely, if the diameter of the pad-cooling hole 6 is smaller than 1 mm, the quantity of polishing slurry to be introduced into the pad-cooling hole 6 may become insufficient, thus possibly resulting in the deterioration of cooling efficiency. If the diameter of the pad-cooling hole 6 is larger than 20 mm, the quantity of polishing slurry to be fed to the surface of the first polishing pad layer 2 for the polishing of the body 20 may become insufficient, thus possibly resulting in the deterioration of polishing rate on the contrary.

The second pad layer 3 is provided, on the surface thereof facing the polishing table 1, with pad-cooling trenches 7 which are radially extended from the center of the second pad layer 3. This pad-cooling trenches 7 are communicated with the hole 6. The number of the pad-cooling trenches 7 may be not limited, but may be confined within the range of 1-32 in general. In the embodiment shown in FIG. 2, eight pad-cooling trenches 7 are radially extended. As for the configuration of the pad-cooling trenches 7, there is not any particular limitation and hence the pad-cooling trenches 7 may be optionally selected from various kinds of configuration such as a rectangular cross-sectional configuration, a V-shaped cross-sectional configuration, a U-shaped cross-sectional configuration, etc.

A polishing slurry is dropped from a nozzle 30 to the center of the polishing pad 5 or the vicinity thereof. As the polishing table 1 is rotated, part of the polishing slurry thus dropped is caused to spread all over the surface of the first pad layer 2 due to the centrifugal force and hence is made available for the polishing of the body 20 such as a semiconductor wafer which is being pressed onto the polishing pad 5 by the polishing head 10. On the other hand, the rest of the polishing slurry is permitted to enter into the cooling hole 6 provided at the center of the polishing pad 5 or the vicinity thereof and to flow into the cooling trenches 7 radially formed in the second pad layer 3. The polishing slurry thus fed to the cooling trenches 7 is then caused to spread all over the underside surface of the second pad layer 3 due to the centrifugal force, thereby cooling the second pad layer 3. The polishing slurry thus used for cooling the second pad layer 3 is subsequently permitted to discharge from the outer periphery of the second pad layer 3. In this case, the second pad layer 3 is cooled by the polishing slurry flowing along the cooling trench 7 and, at the same time, the first pad layer 2 laminated, through the water-proof film 4, on the second pad layer 3 is also cooled, thus cooling the polishing pad 5 entirely.

As explained above, in the case of the polishing pad 5 shown in FIG. 1, the polishing slurry is employed not only for polishing the body 20 but also as cooling liquid for cooling the polishing pad 5. Namely, part of the polishing slurry which has been permitted to enter into the cooling hole 6 is used to cool the polishing pad 5, thus suppressing the rise in temperature of the polishing pad 5 that may be caused to generate due to the friction during the polishing.

According to the prior art, the second pad layer is cooled at first through the polishing table by making use of a cooling device attached to the polishing table and then the first pad layer is cooled through this cooling of the second pad layer. As a result, the cooling effect is considerably limited, thus making it impossible to suppress the deterioration of polishing rate that may be caused due to the rise in temperature of the surface of polishing pad.

Whereas, in the case of the chemical mechanical polishing method according to this embodiment of the present invention, the second pad layer 3 is directly cooled by the polishing slurry and, through this cooling of the second pad layer 3, the first pad layer 2 is cooled, thus making possible to remarkably enhance the cooling efficiency. As a result, the rise in temperature of the polishing surface can be sufficiently suppressed and hence the deterioration of polishing rate can be effectively prevented.

Incidentally, there has been conventionally proposed to cool the polishing pad with a cooling water which is designed to be fed thereto from a line provided separate from the line of polishing slurry. The chemical mechanical polishing method according to this embodiment of the present invention is advantageous over such a proposal in the respect that since the polishing slurry is employed not only for the polishing but also for the cooling of polishing pad, the provision of the line exclusively for the supply of cooling water can be omitted.

In the polishing pad 5 to be employed in this embodiment, the pad-cooling hole 6 is provided only at the center of the polishing pad 5 or the vicinity thereof and is not provided at any other regions of the polishing pad 5. Although there has been conventionally proposed to a polishing pad provided, on the surface thereof, with a large number of holes communicating with the outer peripheral portion thereof, thus creating a slurry-draining channel, such a structure is accompanied with the problem that, due to the provision of these holes all over the surface of polishing pad, the water in the polishing slurry infiltrated from the outer periphery of polishing pad is permitted to ooze out of the holes to the surface of polishing pad. As a result, the concentration of the polishing slurry is caused to reduce, resulting in the deterioration of polishing rate. Whereas, in this embodiment, since the pad-cooling hole is provided only at the center of the polishing pad or in the vicinity thereof, it is possible to obviate such a problem.

In this embodiment, the cooling trench 7 to be formed in the second pad layer 3 may be formed on the surface of the second pad layer 3 which faces the first pad layer 2 as shown in FIG. 3 instead of providing it on the surface of the second pad layer 3 which faces the polishing table 1 as shown in FIG. 1. When the cooling trench 7 is provided, in this manner, on the surface of the second pad layer 3 which faces the first pad layer 2, the polishing slurry penetrated into the cooling hole 6 is enabled to flow into this cooling trench 7 and, therefore, the first pad layer 2 can be directly cooled by the polishing slurry passed through the water-proof film 4. As a result, the effects of suppressing the deterioration of polishing rate can be further enhanced. Incidentally, the pad-cooling hole 6 in this case is simply required to be communicated with the pad-cooling trench 7, the pad-cooling hole 6 is formed in the first pad layer 2 and in the water-proof film 4 and the pad-cooling hole 6 is required to be formed only at a portion of the second pad layer 3 which can be communicated with the cooling trench 7.

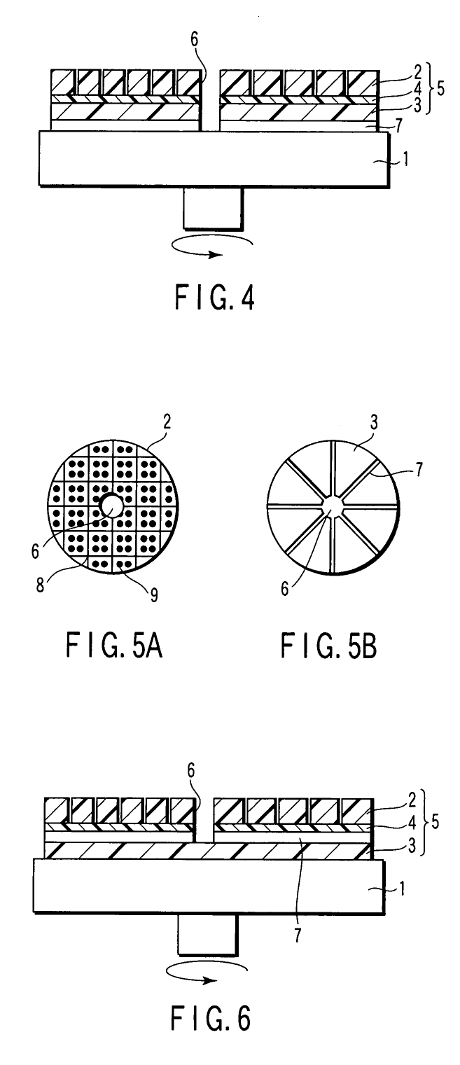

Further, as shown in FIGS. 4-6, the hole and the trench may be provided only in the first pad layer 2 (these hole and trench will be provided so as not to pass through the water proof film 4 and the second pad layer 3). Namely, in the case of the polishing pad 5 shown in FIG. 4, a trench 8 having a lattice-like pattern and a large number of holes 9 are formed in the first pad layer 2 in the structure shown in FIG. 1. In the case of the polishing pad shown in FIG. 6, a trench 8 having a lattice-like pattern and a large number of holes 9 are formed in the first pad layer 2 in the structure shown in FIG. 3. FIG. 5A shows a top plan view of the first pad layer of the polishing pad 5 shown in FIGS. 4 and 6, and FIG. 5B is a plan view of the second pad layer 3 of the polishing pad 5 shown in FIGS. 4 and 6.

In the polishing pad 5 shown in FIGS. 4 to 6, due to the provision of the trench 8 in the first pad layer 2, the polishing slurry is enabled to discharge smoothly. Additionally, due to retention of abrasive grains in the holes 9, the clogging of polishing pad can be prevented, thus making it possible to enhance the stability of polishing.

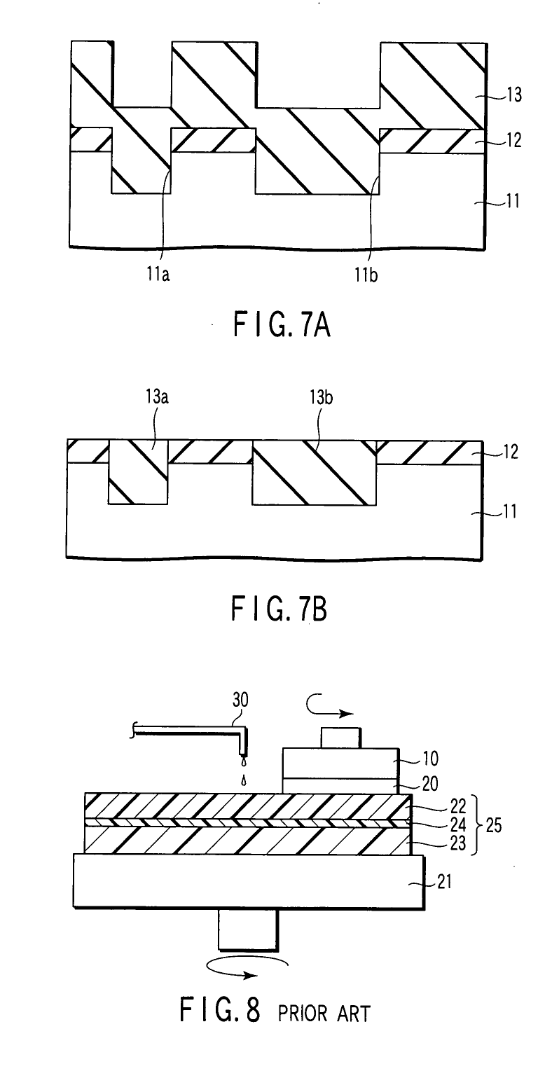

Next, the chemical mechanical polishing method wherein the polishing table and the polishing pad both described above are utilized will be explained taking the process of manufacturing a semiconductor device as one example with reference to FIGS. 7A and 7B.

FIGS. 7A and 7B respectively shows a cross-sectional view illustrating a process for forming an element isolation structure by means of CMP of an oxide film. First of all, as shown in FIG. 7A, trenches (or grooves) 11a and 11b are formed in a silicon substrate 11 and a silicon nitride film 12 is deposited all over the surface of the silicon substrate 11 except the regions thereof where trenches 11a and 11b are formed. Then, by means of CVD method, a silicon oxide film 13 is deposited on the surface of silicon substrate 11, thereby filling the trenches 11a and 11b with the silicon oxide film 13. As shown in FIG. 7A, the surface of the silicon oxide film 13 is accompanied with projected/recessed portions.

Then, by means of CMP method using polishing pads shown in FIGS. 1-6 explained above, the surface of the silicon oxide film 13 is polished. Namely, the semiconductor substrate 11 is mounted on the polishing head so as to enable the silicon oxide film 13 to contact with the polishing pad 5. Then, the silicon oxide film 13 is pressed onto the polishing pad 5 and polishing slurry is fed drop-wise to a central portion of the polishing pad 5. At the same time, the polishing head and the polishing table are rotated to perform the polishing of the silicon oxide film 13. On this occasion, the polishing slurry is used for polishing the silicon oxide film 13 and also for cooling the polishing pad 5 to thereby suppress the rise in temperature of the polishing pad 5 that may be caused to occur due the friction during polishing.

As a result, the polishing can be performed at a stable polishing rate, thus making it possible to obtain an STI structure having the trenches 11a and 11b filled with silicon oxide films 13a and 13b as shown in FIG. 7B.

Next, the present invention will be explained with reference to the examples of the present invention and to comparative examples.

### EXAMPLE 1

F*REX300E®; Ebara Seisakusho Co., Ltd.) was employed as a polishing device. As shown in FIG. 1, in this polishing device, a polishing pad 5 was disposed on the surface of the polishing table 1, this polishing pad 5 being formed of a laminate comprising a first pad layer 2 formed of IC1000®; Nitta Harth Co., Ltd.), and a second pad layer 3 formed of Suba400®; Nitta Harth Co., Ltd.) with a water-proof film 4 formed of an acrylic adhesive being interposed therebetween. This polishing pad 5 was provided, at an approximately central portion thereof, with a pad-cooling hole 6 having a diameter of 10 mm. Further, the second pad layer 3 was provided, on the surface thereof facing the polishing table 1, with a pad-cooling trench 7 having a width of 10 mm and a depth of 5 mm. This pad-cooling trench 7 was composed of eight lines of grooves which were extended radially from the pad-cooling hole 6.

By making use of this polishing device provided with the polishing pad 5 described above, a chemical mechanical polishing treatment was applied to a silicon thermal oxide film. Namely, the polishing table 1 was rotated under the condition wherein a body 20 to be polished, having a silicon thermal oxide film formed thereon, was brought into contact with the polishing pad 5, enabling the silicon oxide film to press onto the polishing pad 5 by means of the polishing head 10 at a pressure of 500 hPa, thereby performing the polishing with the polishing slurry being fed to an approximately central portion of the polishing pad 5. As for the feeding of polishing slurry, a slurry containing 0.5% by weight of cerium oxide was fed to the polishing pad at a flow rate of 190 mL/min and at the same time, an aqueous solution containing 30% by weight of polyacrylic acid was fed to the polishing pad at a flow rate of 2.3 mL/min.

### EXAMPLE 2

The polishing of a silicon thermal oxide film was performed in the same manner as in Example 1 except that a polishing pad having the pad-cooling trench 7 provided on the surface of the second pad layer 3 so as to enable the pad-cooling trench 7 to face the first pad layer 2 as shown in FIG. 3 was employed.

### EXAMPLE 3

The polishing of a silicon thermal oxide film was performed in the same manner as in Example 1 except that a polishing pad having the pad-cooling trench 7 provided on the surface of the second pad layer 3 so as to enable the pad-cooling trench 7 to face the polishing table 1 was employed and that the first pad layer 2 which was also provided with grooves 8 and holes 9 was employed as shown in FIG. 4.

### EXAMPLE 4

The polishing of a silicon thermal oxide film was performed in the same manner as in Example 1 except that a polishing pad having the pad-cooling trench 7 provided on the surface of the second pad layer 3 so as to enable the pad-cooling trench 7 to face the first pad layer 2 was employed and that the first pad layer 2 which was also provided with grooves 8 and holes 9 was employed as shown in FIG. 6.

### COMPARATIVE EXAMPLE 1

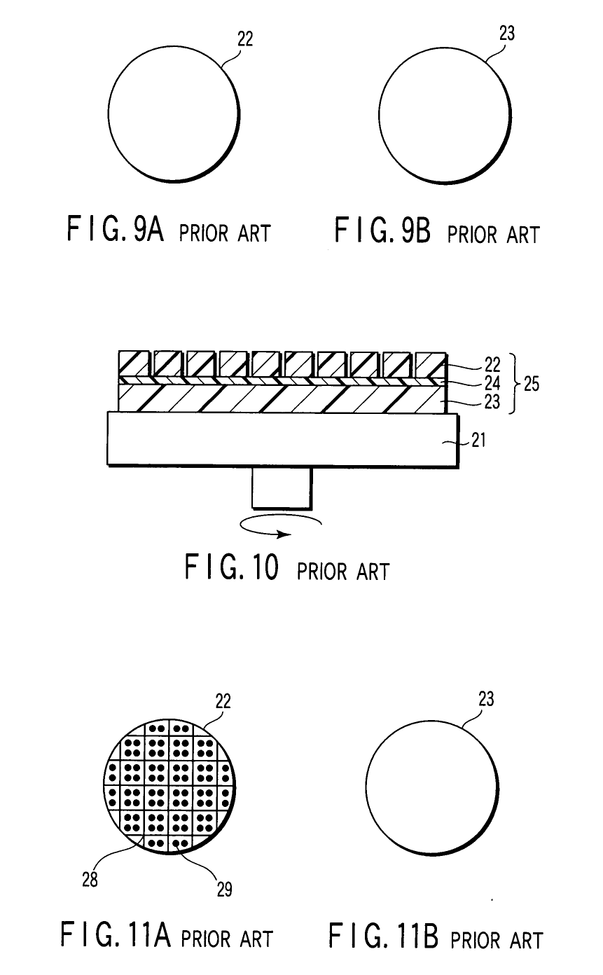

The polishing of a silicon thermal oxide film was performed in the same manner as in Example 1 except that a polishing pad 25 which was formed of a laminate comprising a first pad layer 22, and a second pad layer 23 having no pad-cooling trench with a water-proof film 24 being interposed therebetween was employed as the polishing pad and that the polishing pad 25 was not provided with the pad-cooling hole at all as shown in FIG. 8. Incidentally, FIG. 9A is a top plan view of the first pad layer 22 and FIG. 9B is a plan view showing an underside surface of the second pad layer 23. As seen from FIGS. 9A and 9B, neither the hole nor the trench were formed in any surfaces of these pad layers.

### COMPARATIVE EXAMPLE 2

The polishing of a silicon thermal oxide film was performed in the same manner as in Example 1 except that a polishing pad 25 which was formed of a laminate comprising a first pad layer 22, and a second pad layer 23 with a water-proof film 24 being interposed therebetween was employed as the polishing pad and that the polishing pad 25 was not provided with the pad-cooling hole at all, and grooves 28 and holes 29 are formed only in the first pad layer 22 as shown in FIG. 10. Incidentally, FIG. 11A is a top plan view of the first pad layer 22 and FIG. 11B is a plan view showing an underside surface of the second pad layer 23.

In these Examples 1-4 and Comparative Examples 1 and 2, the surface temperature of the first pad layer was measured and, at the same time, the polishing rate of the thermal oxide film was measured during the step of polishing, thus assessing the stability of the polishing rate. The results obtained are shown in the following Table 1. Incidentally, the stability of polishing rate was estimated according to the following criterion.

⊚: Very good

◯: Good

TABLE 1

| | Ex. 1 | Ex. 2 | Ex. 3 | Ex. 4 | Com. Ex. 1 | Com. Ex. 2 |
|---|---|---|---|---|---|---|
| Surface temp. | 58 | 50 | 59 | 49 | 70 | 67.5 |
| of first pad | | | | | | |
| at 500 hPa | | | | | | |
| in polishing | | | | | | |
| pressure | | | | | | |
| Polishing rate | 620 | 700 | 618 | 720 | 400 | 424 |
| of thermal | | | | | | |
| oxide film | | | | | | |
| (nm/min) | | | | | | |
| Stability of | ◯ | ◯ | ⊚ | ⊚ | ◯ | ⊚ |
| polishing rate | | | | | | |

It will be recognized from above Table 1 that while the surface temperature of the first pad layer in the cases of Examples 1-4 was all as low as 49° C.-59° C., the surface temperature of the first pad layer in the cases of Comparative Examples 1 and 2 was as high as 70° C. and 67.5° C., respectively. Because of this, the polishing rate was all as high as 618-720 nm/min in the cases of Examples 1-4, the polishing rate in the cases of Comparative Examples 1 and 2 was as low as 400 nm/min and 424 nm/min, respectively. From these results, it was possible to recognize the prominent effects of the pad-cooling hole and pad-cooling trench provided in the polishing pads of Examples 1-4.

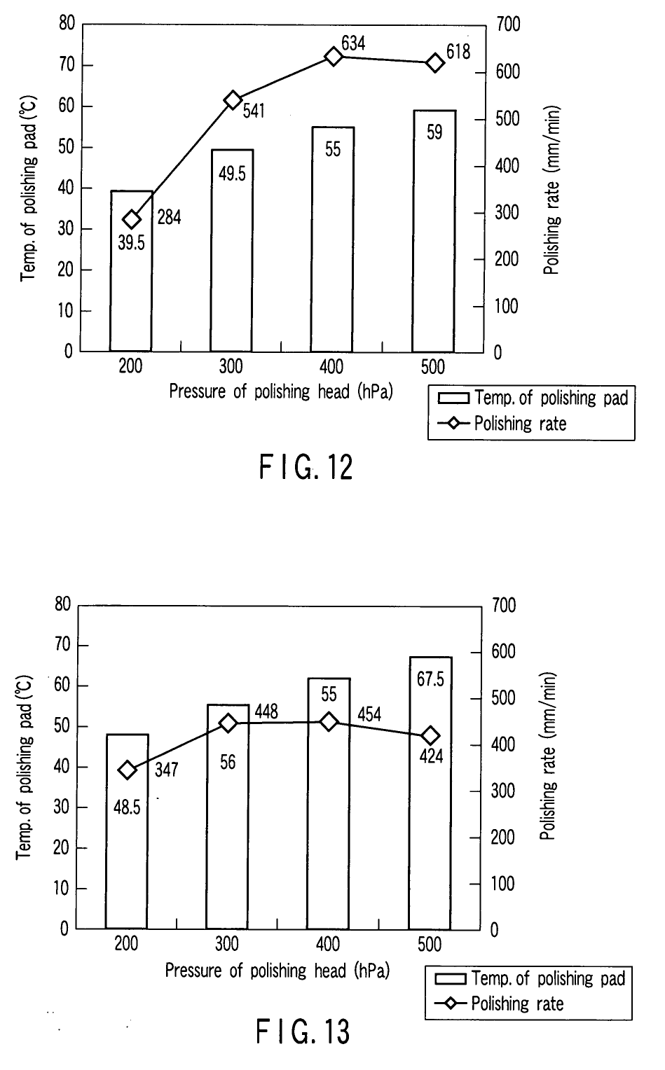

Then, in Example 3, the surface temperature of the first pad layer and the polishing rate were measured while changing the pressure of polishing to obtain the results shown in FIG. 12. From the results shown in FIG. 12, it was possible to recognize that although the surface temperature of the first pad layer was caused to rise more or less as the pressure of polishing was increased, it was possible to maintain a high polishing rate even in the increase of polishing pressure.

On the other hand, when the surface temperature of the first pad layer and the polishing rate were measured while changing the pressure of polishing in Comparative Example 2, it was possible to obtain the results shown in FIG. 13. From the results shown in FIG. 13, it was possible to recognize that the surface temperature of the first pad layer was already high even at the moment of low polishing pressure, that the surface temperature of the first pad layer was caused to increase as the polishing pressure was increased, and that the polishing rate was low as a whole.

It will be recognized from the results shown in FIGS. 12 and 13 that it was possible to perform the polishing at a higher polishing rate by making use of the polishing method of Example 3 as compared with the polishing method of Comparative Example 2.

As described above, according to the embodiments of the present invention, since a pad-cooling hole is provided at the central portion of the polishing pad (or in the vicinity thereof), and a pad-cooling trench is provided in the polishing pad, a polishing slurry is permitted to enter into the pad-cooling hole and to act to cool the polishing pad during the polishing, thus suppressing the deterioration of polishing rate that might has been caused to occur due to the rise in surface temperature of the polishing pad resulting from the friction during the polishing. Therefore, it is now possible to provide a chemical mechanical polishing method which is capable of performing the flattening of a body to be polished within a short time and at a stable polishing rate.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A chemical mechanical polishing method, which comprises bringing a body to be polished into contact with a polishing pad mounted on a rotating polishing table while feeding a polishing slurry to the polishing pad, to chemically and mechanically polish the body;
wherein the polishing pad is formed of a laminate comprising a first pad layer in contact with the body, and a second pad layer positioned on a side of the polishing table with a water-proof film being interposed therebetween, the first pad layer has a pad-cooling hole reaching the second pad layer at a center of the polishing pad or in a vicinity thereof, the second pad layer has a cooling trench radially disposed to interconnect with the pad-cooling hole, and the polishing slurry is fed to a surface of the first pad layer to polish the body, while permitting part of the polishing slurry to pass through the pad-cooling hole to the cooling trench.

2. The method according to claim 1, wherein the cooling trench is provided on a surface of the second pad layer which faces the polishing table.

3. The method according to claim 1, wherein the cooling trench is provided on a surface of the second pad layer which faces the first pad layer.

4. The method according to claim 1, wherein the first pad layer has abrasive grain-retaining holes.

5. The method according to claim 1, wherein the first pad layer has a polishing slurry-discharging trench.

6. The method according to claim 5, wherein the polishing slurry-discharging trench is formed in a lattice pattern on a top surface of the first pad layer.

7. The method according to claim 1, wherein the pad-cooling hole has a diameter ranging from 1 mm to 20 mm.

8. The method according to claim 1, wherein the cooling trench is constituted by 1-32 lines of grooves.

9. The method according to claim 1, wherein the cooling trench has a cross-section selected from the group consisting of a rectangular configuration, a V-shaped configuration and a U-shaped configuration.

10. The method according to claim 1, wherein the first pad layer is formed of rigid polyurethane, the second pad layer is formed of foamed polyurethane, and the water-proof film is formed of an acrylic adhesive or a rubber adhesive.

11. A method for manufacturing a semiconductor device, which comprises:
forming an oxide film on a surface of the semiconductor substrate having a trench formed in an element isolation-forming region in a manner to fill the trench with the oxide film; and
chemically and mechanically polishing a surface of the oxide film to leave the oxide film in the trench selectively, thereby creating an element isolation film comprising the oxide film existing in the trench of the element isolation-forming region, the polishing of the surface of the oxide film being performed by bringing a body to be polished into contact with a polishing pad mounted on a rotating polishing table while feeding a polishing slurry to the polishing pad;
wherein the polishing pad is formed of a laminate comprising a first pad layer to be contacted with the body, and a second pad layer positioned on a side of the polishing table with a water-proof film being interposed therebetween, the first pad layer has a pad-cooling hole reaching the second pad layer at a center of the polishing pad or in a vicinity thereof, the second pad layer has a cooling trench radially disposed to interconnect with the pad-cooling hole, and the polishing slurry is fed to a surface of the first pad layer to polish the body, while permitting part of the polishing slurry to pass through the pad-cooling hole to the cooling trench.

12. The method according to claim 11, wherein the cooling trench is provided on a surface of the second pad layer which faces the polishing table.

13. The method according to claim 11, wherein the cooling trench is provided on a surface of the second pad layer which faces the first pad layer.

14. The method according to claim 11, wherein the first pad layer has abrasive grain-retaining holes.

15. The method according to claim 11, wherein the first pad layer has a polishing slurry-discharging trench.

16. The method according to claim 15, wherein the polishing slurry-discharging trench is formed in a lattice pattern on a top surface of the first pad layer.

17. The method according to claim 11, wherein the pad-cooling hole has a diameter ranging from 1 mm to 20 mm.

18. The method according to claim 11, wherein the cooling trench is constituted by 1-32 lines of grooves.

19. The method according to claim 11, wherein the cooling trench has a cross-section selected from the group consisting of a rectangular configuration, a V-shaped configuration and a U-shaped configuration.

20. The method according to claim 11, wherein the first pad layer is formed of rigid polyurethane, the second pad layer is formed of foamed polyurethane, and the water-proof film is formed of an acrylic adhesive or a rubber adhesive.
